(19) United States
(12) Patent Application Publication
(10) Pub. No.: US 2007/0230121 A1
(43) Pub. Date: Oct. 4, 2007

(54) Heat sink device

(75) Inventor: Kuei-Hua Chen, Taipei (TW)

Correspondence Address: EDWARDS ANGELL PALMER & DODGE LLP, P.O. BOX 55874, BOSTON, MA, 02205, US

(73) Assignee: Inventec Corporation, Taipei (TW)

(21) Appl. No.: 11/395,946

(22) Filed: Mar. 30, 2006

(51) Int. Cl. H05K 7/20

(52) U.S. Cl. 361/695

(57) ABSTRACT

A heat sink device which is used to bond to a stand-alone blade server for dissipating heat produced by the stand-alone blade server is provided. The heat sink device comprises a cabinet having a bonding end and a mounting end opposed to the bonding end, and a fan structure setting in the mounting end of the cabinet. The bonding end is bonded to the stand-alone blade server, and the fan structure is used to dissipate heat produced by the stand-alone blade server to the air through a crossover passage formed between the bonding end and the mounting end, such that the heat produced by the stand-alone blade server can be dissipated effectively.

### BACKGROUND OF THE INVENTION

1. Field of the Invention

The present invention relates to a heat sink device and, more particularly to a heat sink device which is used for computer servers.

2. Description of Related Arts

Generally, a super large computer blade server system can hold more than 16 stand-alone blade servers, but there is no heat sink device can be used therein for dissipating heat as the space between the stand-alone blade servers is too shallow.

However, the stand-alone blade servers of such super large blade server system which are limited to its space can not provide an effective heat sink device, therefore the stand-alone blade servers may be down as the heat can not be dissipated effectively and has gathered therein for a long time.

As a result, the present subject to be solved is how to provide effectively heat sink for stand-alone blade servers.

### SUMMARY OF THE INVENTION

In views of the above-mentioned problems of the prior art, it is a primary objective of the present invention to provide a heat sink device for effectively dissipating heat produced by a stand-alone blade server.

It is another objective of the present invention to provide a heat sink device which can be mounted to a stand-alone blade server easily without using tools.

It is a further objective of the present invention to provide a heat sink device which does not occupy inner space of a stand-alone blade server.

To achieve the above-mentioned and other objectives, a heat sink device is provided in the present invention, which comprises: a cabinet having a bonding end and a mounting end opposed to the bonding end, wherein the bonding end is bonded to a stand-alone blade server and at least the mounting end of the cabinet is exposed from the stand-alone blade server; and a fan structure setting in the mounting end of the cabinet, wherein the fan structure is used to dissipate heat produced by the stand-alone blade server to the air through a crossover passage formed between the bonding end and the mounting end.

Furthermore, at least one bump is formed on the outer face of the bonding end of the cabinet, for providing sufficient force of friction between the cabinet and the stand-alone blade server, such that the cabinet can be steadily bonded to the stand-alone blade server; wherein the bump may be s-shaped, round, strip or other shapes.

The fan structure comprises at least one fan and a frame for holding the fan, and the fan structure is locked to the cabinet by a plurality of bonding components passing through openings of the cabinet and openings of the fan structure; wherein the bonding components may be bolts, screws or other equivalents.

As a result, the heat sink device of the present invention can be applied in stand-alone blade servers for dissipating heat effectively, therefore the heat sink problem of the prior art can be solved.

### BRIEF DESCRIPTIONS OF THE DRAWINGS

FIG. 1 is an exploded view showing a heat sink device of the present invention;

FIG. 2 is a three-dimensional view showing a heat sink device of the present invention being applied in an A-type stand-alone blade server; and

FIG. 3 is a three-dimensional view showing a heat sink device of the present invention being applied in a B-type stand-alone blade server.

### DETAILED DESCRIPTIONS OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

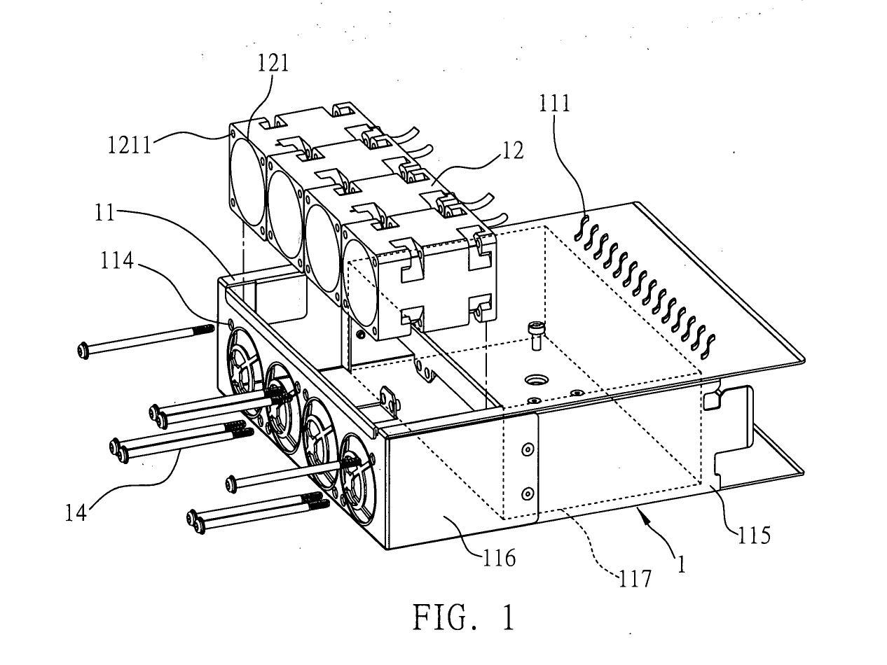

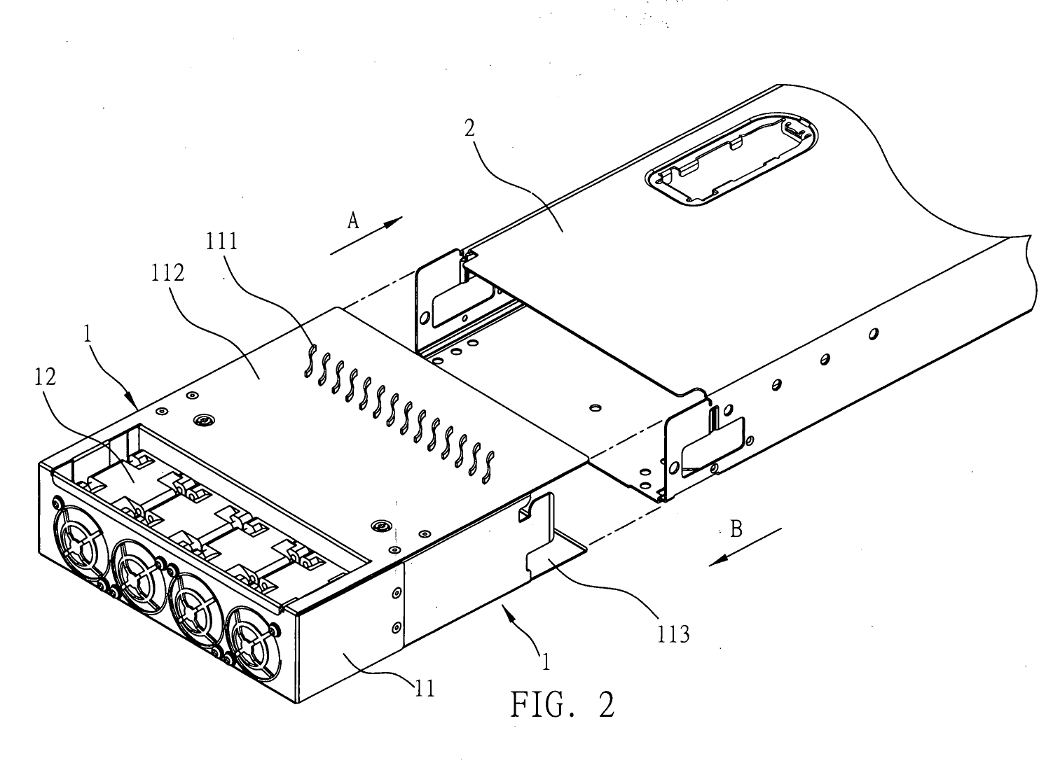

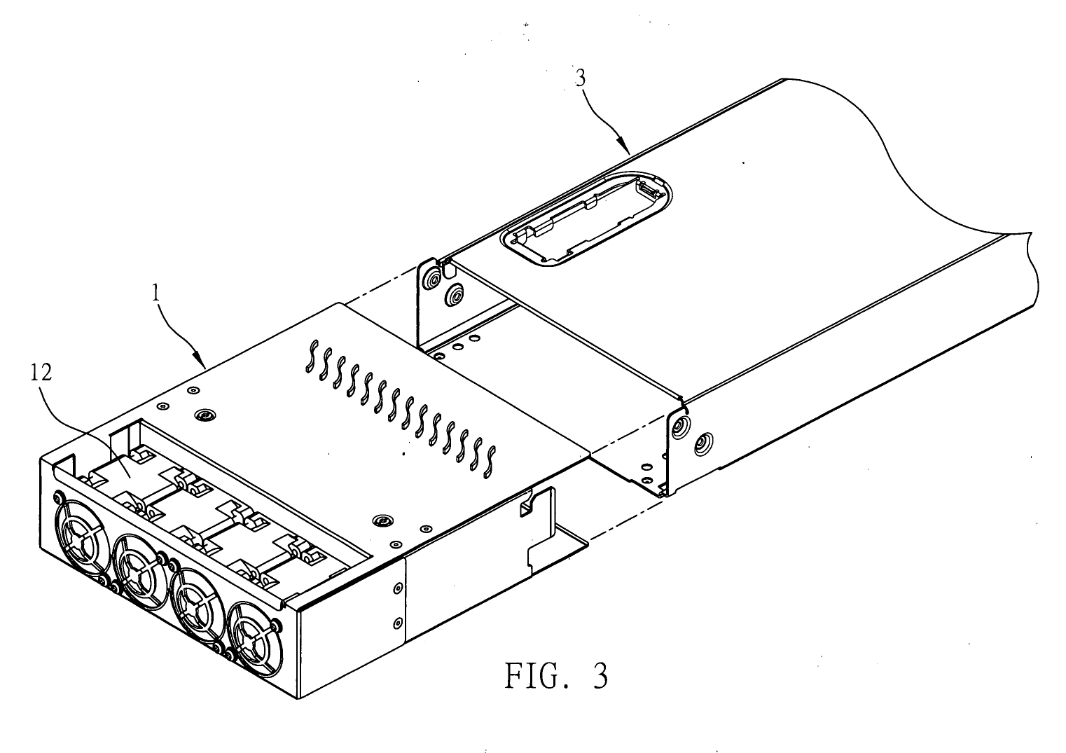

Please referring to FIG. 1 to 3, wherein FIG. 1 is an exploded view showing a heat sink device of the present invention; FIG. 2 is a three-dimensional view showing a heat sink device of the present invention being applied in an A-type stand-alone blade server; and FIG. 3 is a three-dimensional view showing a heat sink device of the present invention being applied in a B-type stand-alone blade server. As shown in FIG. 1, the heat sink 1 comprises a cabinet 11 and a fan structure 12.

As shown in FIGS. 1 and 2, the cabinet 11 has a bonding end 115 and a mounting end 116 opposed to the bonding end 115, wherein the bonding end 115 is bonded to a stand-alone blade server 2 and at least the mounting end 116 of the cabinet 11 is exposed from the stand-alone blade server 2. Furthermore, at least one bump 111 is formed on the outer face of the bonding end 115 of the cabinet 11, for providing sufficient force of friction between the cabinet 11 and the stand-alone blade server 2, wherein the bump 111 is s-shaped bump. It should be noted that the shape of the bump 111 is selectively designed for providing sufficient force of friction between the cabinet 11 and the stand-alone blade server 2, so it can be other shapes such as round, strip or sawtooth-shaped.

The fan structure 12 comprises at least one fan 121, and the fan structure 12 is locked to the mounting end 116 of the cabinet 12 by a bonding component 14 passing through an opening 113 of the cabinet 11 and an opening 1211 of the fan structure 12; wherein the bonding component 14 may be a bolt, a screw or other equivalent. The fan structure 12 is used to dissipate heat produced by the stand-alone blade server 2 to the air through a crossover passage 117 formed between the bonding end 115 and the mounting end 116 of the cabinet 11.

FIG. 2 is a three-dimensional view showing a heat sink device of the present invention being applied in an A-type stand-alone blade server. As shown in the figure, a first board face 112 of the cabinet 11 and a second board face 113 opposed to the first board face 112 both have a plurality of s-shaped bumps 111 for increasing force of friction of the stand-alone server 2, such that falling off of the heat sink device 1 caused by shaking the fan structure 12 can be prevented from occurrence.

As shown in FIG. 2, while mounting the heat sink device 1 to the stand-alone blade server 2, firstly the cabinet 11 is held by hand and moved along a first moving direction A, then the s-shaped bumps 111 of the first board face 112 and the second board face 113 enter and clamp to inner sides of the stand-alone blade server 2, force of friction is produced as the bumps 111 are under the pressure of the stand-alone blade server 2, so falling off of the heat sink device 1 caused by shaking the fan structure 12 can be prevented from occurrence. While demounting the heat sink device 1 from the stand-alone blade server 2, the cabinet 11 is held by hand and moved along a second moving direction B opposed to the first moving direction A, thereby the heat sink device 1 is removed.

FIG. 3 is a three-dimensional view showing a heat sink device of the present invention being applied in a B-type stand-alone blade server. As shown in the figure, the difference between FIG. 2 and FIG. 3 is that the heat sink device 1 can be used not only in A-type stand-alone blade server 2, but also in B-type stand-alone blade server 3 or other stand-alone blade server with different type or structure. However, the width of the stand-alone blade server must be fit to the heat sink device 1, but the length of the stand-alone blade server is not limited.

Moreover, it should be noted the heat sink device 1 can be applied according to practical requests and not limited to the above mentioned stand-alone blade server in the present invention, i.e. the heat sink device can also be used in an electronic device which is fit to the heat sink device 1 for dissipating heat.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed:

1. A heat sink device, comprising:
a cabinet having a bonding end and a mounting end opposed to the bonding end, wherein the bonding end is bonded to a stand-alone blade server and at least the mounting end of the cabinet is exposed from the stand-alone blade server; and
a fan structure setting in the mounting end of the cabinet, wherein the fan structure is used to dissipate heat produced by the stand-alone blade server to the air through a crossover passage formed between the bonding end and the mounting end.

2. The heat sink device of claim 1, wherein at least one bump is formed on the outer face of the bonding end of the cabinet, for providing sufficient force of friction between the cabinet and the stand-alone blade server.

3. The heat sink device of claim 2, wherein the bump is one of s-shaped bump, round bump and strip bump.

4. The heat sink device of claim 1, wherein the fan structure comprises at least one fan.
